(19) United States
(12) Patent Application Publication
(10) Pub. No.: US 2017/0301772 A1
(43) Pub. Date: Oct. 19, 2017

(54) GaN DEVICES FABRICATED VIA WAFER BONDING

(71) Applicants: Robert M. Radway, Boston, MA (US); Tomas A. Palacios, Belmont, MA (US)

(72) Inventors: Robert M. Radway, Boston, MA (US); Tomas A. Palacios, Belmont, MA (US)

(21) Appl. No.: 15/489,083

(22) Filed: Apr. 17, 2017

Related U.S. Application Data
(60) Provisional application No. 62/323,050, filed on Apr. 15, 2016.

(51) Int. Cl. H01L 29/66; H01L 21/02; H01L 29/778; H01L 29/205; H01L 29/10; H01L 21/308; H01L 21/306; H01L 21/18; H01L 21/683; H01L 29/20

(52) U.S. Cl. CPC H01L 29/66462; H01L 21/6835; H01L 21/02458; H01L 21/0254; H01L 29/7787; H01L 29/205; H01L 29/2003; H01L 29/1033; H01L 21/02381; H01L 21/3085; H01L 21/30612; H01L 21/30604; H01L 21/187; H01L 21/0262; H01L 2221/68345; H01L 2221/68363; H01L 2221/68381

(57) ABSTRACT

A wafer bonding technique to fabricate GaN devices is disclosed. In this technique, a GaN layer (or a GaN stack including at least one GaN layer) is fabricated on a first substrate (e.g., a silicon substrate) and has a high quality surface with a dislocation density less than 10¹⁰/cm². The assembly of the first substrate and the GaN layer is then bonded to a second substrate (e.g., a carbide substrate or an AlN substrate) by coupling the high quality surface to the second substrate. The high quality of the GaN surface in contact with the carbide substrate creates a good thermal contact. The first substrate is etched away to expose a GaN surface for further processing, such as electrode formation.

### CROSS-REFERENCES TO RELATED APPLICATIONS

This application claims priority to U.S. Application No. 62/323,050, filed Apr. 15, 2016, entitled “GAN-ON-SIC HIGH ELECTRON MOBILITY TRANSISTOR FABRICATION VIA WAFER BONDING,” which is hereby incorporated herein by reference in its entirety.

### BACKGROUND

Gallium nitride (GaN) is a wide bandgap semiconductor that has a wide range of applications. For example, GaN high electron mobility transistors (HEMTs) are commonly found in high-frequency power amplifiers (PAs), which in turn are used in broadcasting technologies including cellular communications and radar applications. GaN HEMTs have a higher power density compared to other technologies, such as silicon (Si) laterally diffused metal oxide semiconductor (LDMOS) transistors, silicon carbide (SiC) metal semiconductor field effect transistors (MESFETs), and gallium arsenide (GaAs) HEMTs. This higher power density can be attributed to the material properties of GaN, including the wide bandgap, high breakdown field, high electron mobility, excellent charge density, and high thermal conductivity.

FIG. 1 shows a schematic of a conventional GaN HEMT 100. The transistor 100 includes a SiC substrate 110 that has high thermal conductivity. Due to the lattice mismatch between SiC and GaN, a nucleation layer 112 including AlN is usually deposited on the SiC substrate 110 in order to grow a high quality GaN layer 120 (e.g., made of crystalline GaN) with a smooth epitaxial surface. Typically, a GaN buffer layer 114 forms immediately above the nucleation layer 112 before the high quality GaN layer 120 is formed. An AlGaN layer 130 is disposed on the high quality GaN layer 120. Three metal electrodes, including a source electrode 140a, a gate electrode 140b, and a drain electrode 140c, are disposed on the AlGaN layer 130.

Due to a difference in the spontaneous polarization fields of GaN and AlGaN, a two dimensional electron gas (2DEG) 125 forms at the interface between the high quality GaN layer 120 and the AlGaN layer 130. No doping is needed to populate the 2DEG. Another benefit is that the native 2DEG carrier concentration can be extremely high (e.g., greater than 1×10¹³ cm⁻²) and high quality devices can achieve channel mobilities of over 2000 cm²/Vs.

The nucleation layer 112 and the buffer layer 114 usually have a high concentration of dislocations. During the initial growth of GaN (buffer layer 114), grains form but eventually coalesce into one layer. This seeding effect can introduce lattice dislocations at the grain boundaries. While the nucleation layer 112 is used to grow crystal GaN, it also has threading dislocations within the layer itself. Dislocations in the buffer layer 114 and the nucleation layer 112 can cause diffuse scattering of heat carrying phonons, thereby impeding heat flow through the epitaxy. This can increase self-heating of the transistor 100 and impose a limitation on the power density the transistor 100 can achieve.

### SUMMARY

Embodiments of the present technology generally relate to semiconductor devices fabricated via wafer bonding. In one example, a method includes forming a GaN layer on a first substrate. The GaN layer has a first surface in contact with the first substrate and a second surface opposite the first surface. The method also includes bonding the second surface to a second substrate comprising at least one of SiC or AlN. The method also includes etching the first substrate to expose the first surface of the GaN layer.

In another example, a method includes forming a GaN layer on a first substrate and etching the first substrate to expose a first surface of the GaN layer. The method also includes bonding the first surface of the GaN layer to a second substrate comprising at least one of SiC or AlN.

In yet another example, an apparatus includes a substrate made of at least one of SiC or AlN. The apparatus also includes a GaN layer disposed on the substrate. The GaN layer has a first surface in contact with the substrate and a second surface opposite the first surface. The GaN layer has a dislocation density substantially equal to or less than 10¹⁰/cm² on the first surface.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1 shows a schematic of a conventional GaN transistor including a nucleation layer to grow crystalline GaN.

FIGS. 2A-2D illustrate a method of fabricating GaN devices via wafer bonding.

FIGS. 3A-3D illustrate a method of fabricating a GaN high electron mobility transistor (HEMT) using wafer bonding.

FIGS. 4A-4D illustrate a method of fabricating GaN devices using back end etching before wafer bonding.

FIGS. 5A-5D illustrate a method of fabricating a GaN HEMT using a handle wafer to facilitate wafer bonding.

FIG. 6A illustrates a bonding configuration using Ga—C bonds to bond a GaN substrate with a SiC substrate.

FIG. 6B illustrate a bonding configuration using Ga—Si bonds to bond a GaN substrate with a SiC substrate.

FIG. 7 illustrates a method of bonding GaN with SiC.

FIGS. 8A and 8B show a cross sectional view and a side view, respectively, of an apparatus for bonding a GaN substrate with another substrate.

FIG. 9 shows an image of a GaN substrate bonded to a SiC substrate.

FIG. 10A shows a He⁺ ion microscopy image of a GaN substrate bonded to a SiC substrate illustrating voids at a scribed edge.

FIGS. 10B and 10C are side views of the GaN substrate bonded to the SiC substrate shown in FIG. 10A.

FIGS. 11A and 11B show scanning electron microscopy (SEM) images of GaN substrates including stress relieving channels.

FIG. 12 illustrates a model to simulate thermal performance of GaN devices fabricated via wafer bonding.

FIGS. 13A and 13B show calculated results of temperature increase below the gate and on the surface, respectively, of the model shown in FIG. 12.

FIG. 14 illustrates a model used to simulate thermal performance of GaN transistors fabricated via wafer bonding.

FIGS. 15A and 15B show calculated results of temperature increase below the gate and on the surface, respectively, using the model shown in FIG. 14.

### DETAILED DESCRIPTION

Methods of Fabricating GaN Devices Via Wafer Bonding

To address the limitation on thermal properties imposed by nucleation layers and buffer layers in conventional GaN high electron mobility transistors (HEMTs), methods, apparatus, and systems described herein employ a wafer bonding technique to fabricate GaN devices. In this technique, a GaN layer (or a GaN stack including at least one GaN layer) is fabricated on a first substrate (e.g., a silicon substrate) and has a high quality surface. The assembly of the first substrate and the GaN layer is then bonded to a carbide substrate (or an AlN substrate) by coupling the high quality surface to the carbide substrate. The high quality of the GaN surface in contact with the carbide substrate leads to good thermal contact. The first substrate is etched away to expose a GaN surface for further processing.

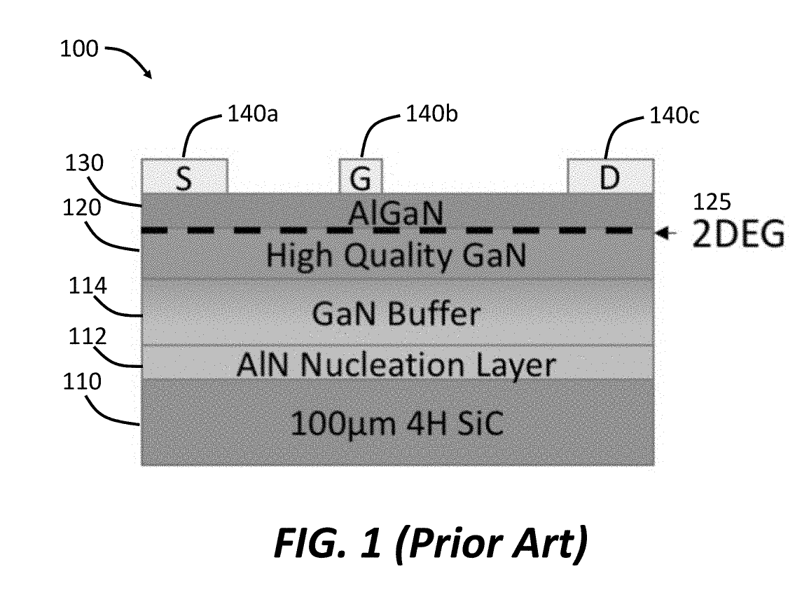

This wafer bonding technique has at least two advantages. First, the wafer bonding technique can reduce thermal boundary resistance because the interface between the GaN layer and the substrate does not include a nucleation layer. In contrast, conventional GaN devices based on epitaxial growth of GaN usually include a nucleation layer (e.g., 112 in FIG. 1) that has a large thermal resistance. Epitaxial growth without a nucleation layer usually leads to a GaN layer where the first 100 nm from the growth substrate has a high dislocation density (and accordingly high thermal boundary resistance) due to lattice mismatch between GaN and the substrate material. Second, the exact thickness of the GaN layer can be controlled to optimize the thermal performance of the structure. For example, the GaN layer can be etched to adjust its thickness after the first substrate is removed. In comparison, GaN layers fabricated from conventional growth techniques are usually greater than a threshold thickness (e.g., greater than 100 nm) in order to achieve a high quality surface.

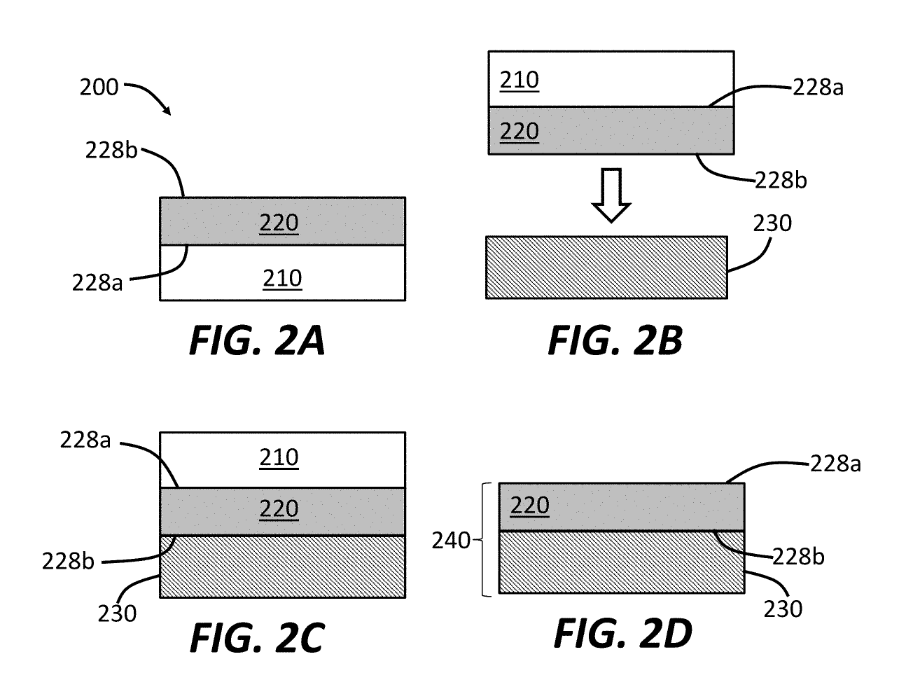

FIGS. 2A-2D illustrate a method 200 of fabricating GaN devices via wafer bonding. The method 200 includes forming a GaN layer 220 on a first substrate 210 (also referred to as a growth substrate 210), as shown in FIG. 2A. In one example, the GaN layer 220 can be formed via a molecular beam epitaxy (MBE) process. In another example, the GaN layer 220 can be formed via a metal organic chemical vapor deposition (MOCVD) process. The growth substrate 210 can include various materials to support the growth of the GaN layer 220. For example, the growth substrate 210 can include sapphire, Si, and SiC. In addition, AlN, ZnO₂, bulk GaN, and graphene can also be used for the growth substrate 210.

The GaN layer 220 includes a first surface 228a in contact with the growth substrate 210 and a second surface 228b that is exposed for further processing. The thickness of the GaN layer 220 can be substantially equal to or greater than 100 nm (e.g., about 100 nm, about 200 nm, about 300 nm, about 500 nm, about 1 μm, about 2 μm, about 3 μm, or greater, including any values and sub ranges in between). In this case, the second surface 228b of the GaN layer 220 can have good material quality. For example, the dislocation density on the second surface 228b can be substantially equal to or less than 10¹⁰/cm² (e.g., about 10¹⁰/cm², about 5×10⁹/cm², about 10⁹/cm², about 5×10⁸/cm², about 10⁸/cm², about 5×10⁷/cm², about 10⁷/cm², about 5×10⁶/cm², about 10⁶/cm², or less, including any values and sub ranges in between).

FIG. 2B shows that the assembly of the GaN layer 220 on the growth substrate 210 is bonded to a second substrate 230 (also referred to as a device substrate 230 or a target substrate 230) via the second surface 228a. The second substrate 230 can include SiC or AlN, which has low thermal resistance and is suitable for transistors, power electronics, and other applications. The resulting stack is shown in FIG. 2C. The first surface 228a of the GaN layer 220 is in contact with the growth substrate 210, and the second surface 228b of the GaN layer 220 is in contact with the target substrate 230.

In one example, the bonding between the GaN layer 220 and the target substrate 230 can be achieved by treating the second surface 228b of the GaN layer 220 with Ar plasma, followed by pressing the second surface 228b of the GaN layer 220 against the target substrate 230 at a high temperature (e.g., about 600° C., about 700° C., about 800° C., or about 900° C., including any values and sub ranges in between). In another example, the Ar plasma treatment can be performed on the surface of the target substrate 230. In yet another example, the Ar plasma treatment can be performed on both the second surface 228b of the GaN layer 220 and the surface of the target substrate 230. Other methods of surface treatment includes UV Ozone excitation, HF excitation, and HCl acid excitation, among others (see more details below).

FIG. 2D shows that the growth substrate 210 is etched away, leaving a stack 240 including the GaN layer 220 disposed on the target substrate 230 via the second surface 228a. As described above, the second surface 228a can have a low dislocation density. In addition, there is no nucleation layer between the target substrate 230 and the GaN layer 220. These features lead to a reduced thermal boundary resistance of the stack 240, which can be used as a platform to fabricate various electronic devices, such as transistors, light emitting diodes (LEDs), and GaN based sensors.

The growth substrate 210 can be removed via various methods. In one example, the growth substrate 210 includes silicon and can be removed via, for example, deep reactive-ion etching (DRIE) etching using SF₆ plasma. DRIE etching can realize selective removal of Si over the underlying GaN layer 220. Therefore, this etching technique can preserve the smoothness of the first surface 228a of the GaN layer 220.

In another example, the growth substrate 210 can be mechanically removed via lapping. In some cases, the growth substrate 210 can be more than 500 μm thick (e.g., about 500 μm, about 1 mm, about 1.5 mm, or more, including any values and sub ranges in between). In this case, lapping can be an efficient technique for quickly removing the growth substrate to expose the first surface 228a of the underlying GaN layer 220.

In some cases, the lapping of the growth substrate 210 can be realized using an abrasive paper with SiC grit or diamond grit. In one example, lapping can start with rough 120-grit SiC paper, which has a grit size of about 140 μm. The lapping rate at this step can be about 25 μm/min. This rough paper can be used to remove a majority of the growth substrate 210 (e.g., about 60%, about 65%, about 70%, about 75%, or more, including any values and sub ranges in between). For example, for a 1 mm growth substrate, this 120-grit SiC paper can be used to remove the first 750 μm or more. Then 400-grit SiC paper, which has a grit size of about 40 μm, is used to remove another 10% to about 30% of the growth substrate (e.g., about 10%, about 15%, about 20%, about 25%, or about 30%, including any values and sub range in between). The remaining portion of the growth substrate 210 can be removed using 800-grit SiC paper, which has a grit size of about 25 μm. This paper can also be used to polish the surface until the surface is visibly reflective.

Alternatively or additionally, a diamond paper can also be used to perform substrate lapping. For example, 600-grit diamond paper, which has a grit size of about 30 μm, can be used to remove Si from the growth substrate 210 as well as to polish the lapped surface.

After the lapping, an optional or additional polishing step, such as a chemical mechanical planarization (CMP) process, can be performed to reduce the surface roughness of the stack 240. In this process, polishing pads and diamond liquid slurry can be used to polish the stack 240. The stack 240 can be held in place by a vacuum carrier such that the first surface 228a is exposed. The carrier and the stack 240 can be slowly brought into contact with a rotating platen, which is covered by a polishing pad. With a controlled downward force, the first surface 228a can be polished by the slurry.

In yet another example, the removal of the growth substrate 210 can be realized via a combination of mechanical removal and reaction ion etching (RIE). For example, a first portion of the growth substrate 210 can be removed by lapping and the rest of the growth substrate 210 can be removed via RIE etching. The first portion can be about 80% to about 95% (e.g., about 80%, about 85%, about 90%, about 95%, including any values and sub ranges in between). The chemistry used in the RIE etching can include a straight SF₆ isotropic etch process with 600 Watts of radio frequency (RF) power. The stack 240 can be loaded onto a coated quartz wafer. A Kapton tape can be used to secure the stack 240 to the wafer.

In yet another example, the growth substrate 210 can be removed via XeF₂ etching. In yet another example, wet etches, such as HNA etch using Acetic, nitric, and hydrofluoric acid, can also be used to remove the growth substrate 210.

A cleaning step can be performed after the removal of the growth substrate 210. In one example, the stack 240 can be cleaned using a Piranha solution, which usually includes a mixture of sulfuric acid (H₂SO₄) and hydrogen peroxide (H₂O₂). In another example, an HF dip can also be used to clean the stack 240. In this case, the surface 228a can be exposed to a 2 minute dip in 10:1 H₂O:HF for cleaning.

The GaN layer 220 in the stack can also be partially etched to control the thickness of the GaN material so as to optimize thermal and electrical performance. This etching step can also clean the first surface and/or remove some dislocations.

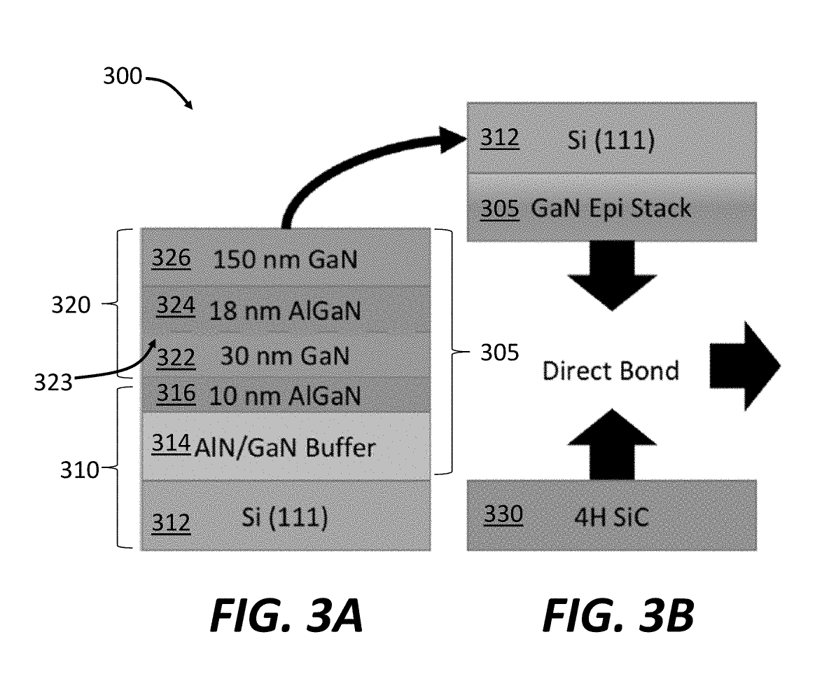

In one example, the GaN layer 220 can be etched using Cl₂/BCl₃ plasma, where chlorine can be the primary etchant and BCl₃ can act as a source of heavy ions for bombardment. The recipe can include 20 sccm of Cl₂ and 4 sccm of BCl₃. Electron cyclotron resonance (ECR) can be used to generate the Cl₂/BCl₃ plasma. With 150 W of ECR power and 75 W of RF platen bias power, the etching rate can be about 250 nm per minute at 40 about ° C. This high etching rate can be efficient to etch a thick GaN layer, such as a GaN buffer layer (see, e.g., FIGS. 3A-3D). When only a thin layer of GaN is removed from the stack 240 (e.g., for polishing and/or cleaning purposes), the power to generate the plasmas can be reduced so as to decrease the etching rate.

In another example, the GaN layer 220 can be etched using a modified chemistry including an equivalent CF₄ density as BCl₃ (a C12/BCl₃/CF₄ solution). This addition can reduce pillaring during etching, while still maintaining a moderate etch rate. The surface of the resulting GaN surface can maintain high smoothness, thereby facilitating subsequent processing, such as electrode formation.

Methods of Fabricating GaN Transistors Via Wafer Bonding

FIGS. 3A-3D illustrate a method 300 of fabricating GaN transistors using a wafer bonding technique. In the method 300, a GaN stack 320 is formed on a growth substrate 310. The growth substrate 310 further includes an AlGaN layer 316 disposed on a buffer layer 314, which in turn is disposed on a silicon substrate 312. The GaN substrate 320 further includes a first GaN layer 322, an AlGaN layer 324 disposed on the first GaN layer 322, and a second GaN layer 326 disposed on the AlGaN layer 324. A 2DEG layer 323 can be formed between the first GaN layer 422 and the AlGaN layer 324. The first GaN layer 322 is grown on the AlGaN layer 316 so as to couple the GaN stack 320 with the growth substrate 310. The buffer layer 314, the AlGaN layer 316, and the entire GaN stack 320 are collectively referred to as a GaN epi stack 305 as illustrated in FIG. 3A.

FIG. 3B shows that the GaN epi stack 305 (together with the silicon substrate 310) is bonded to a target substrate 330 by contacting the second GaN layer 326 with the target substrate 330. The target substrate 330 can include SiC or AlN. The resulting assembly is shown in FIG. 3C. The growth substrate 310 and a portion of the first GaN layer 322 are then removed to expose the first GaN layer 322 for further processing. A major portion of the silicon substrate 312 can be mechanically removed using the lapping techniques described above. The buffer layer 314, the AlGaN layer 316, and part of the first GaN layer 322 can be etched away using selective etching techniques.

In some cases, the AlGaN layer 316 in the growth substrate 310 can function as an etch stop. For example, a first type of etching (e.g., Cl₂/BCl₃ plasma) can be used to etch the buffer layer 314 but not the AlGaN layer 316. Accordingly, the etching can stop at the AlGaN layer 316. Alternatively, SF₆/BCl₃ plasma etching can also be used at this step, where the SF₆ can reduce the etch rate in Al-containing layers, thereby providing a smooth surface after etching. Then a selective etch is used to remove the rest of the buffer layer 314 (but not the AlGaN layer 316). The regular etch can then be used to etch through the AlGaN layer 316 and into the next layers of GaN.

The thinning of the first GaN layer 322 (i.e., the reduction of thickness of the first GaN layer 322) can be about 10 nm to about 50 nm (e.g., about 10 nm, about 20 nm, about 30 nm, about 40 nm, about 50 nm, including any values and sub ranges in between). The thinning can clean the surface of the first GaN layer 322. The thinning may also remove a layer of GaN material having a high dislocation density.

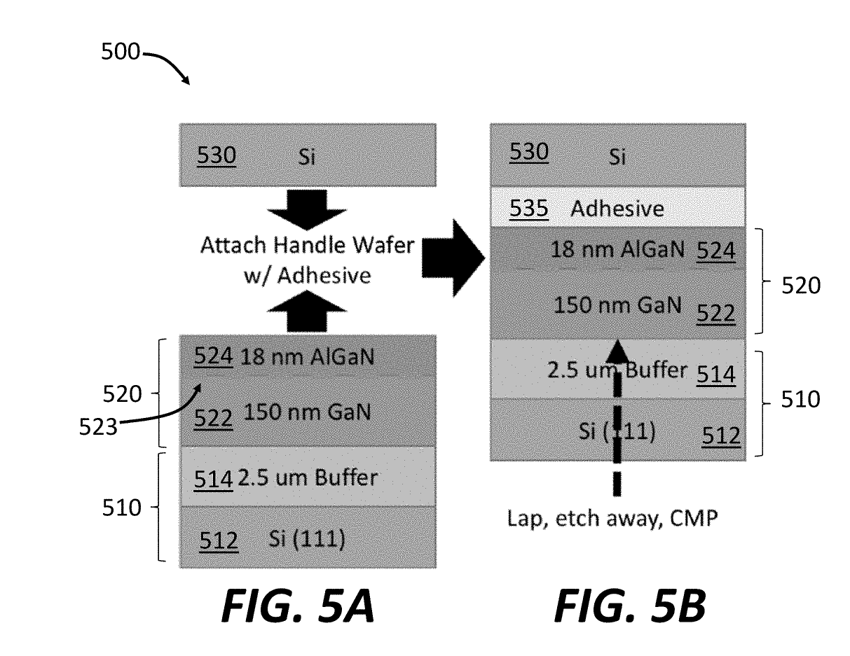

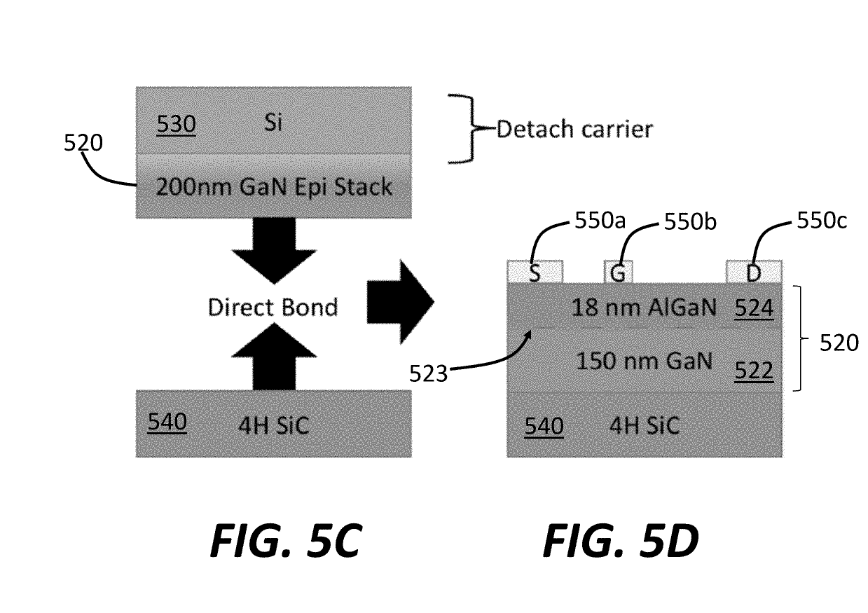

In one example, the thinning can expose the N-face (i.e. nitrogen face) of the first GaN layer 322. In another example, the thinning can expose the Ga-face (i.e. gallium face, see FIGS. 6A and 6B) of the first GaN layer 322. The N-face and Ga-face of GaN are usually determined by the growth process. More specifically, whatever face is originally exposed on top by growth, the opposite face can be exposed by the etching process. The faces can be used to determine polarity, i.e., effective lattice orientation. In practice, there are slight differences in etch rates and/or chemistry makeup in etching the two types of faces. The N-face is generally more reactive and therefore can use slower etch (e.g., using less aggressive etching solutions).

FIG. 3D shows that a source electrode 340a, a gate electrode 340b, and a drain electrode 340c (collectively referred to as electrodes 340) are formed on the first GaN layer 322 to construct a transistor. The electrodes 340 can be formed by depositing a metal layer on the first GaN layer 322 and then define the electrodes 340 via lithography techniques. The transistor shown in FIG. 3D has a reduced thermal boundary resistance (TBR) between GaN layer 322 and the target substrate 330 due to lack of interlayer in the bonding and the high quality of the bonded GaN surface.

Methods of Fabricating GaN Devices Using Back Etching in Wafer Bonding

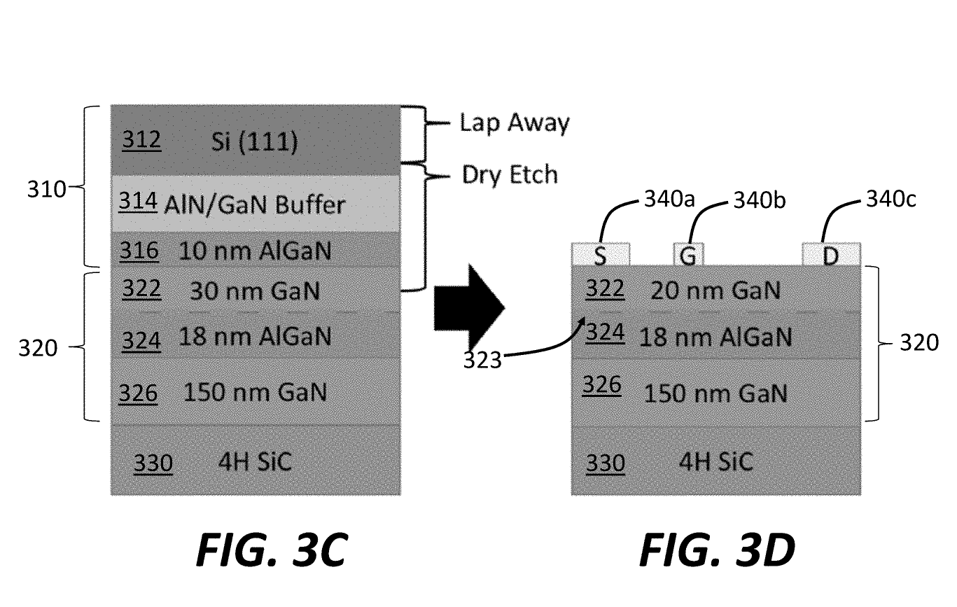

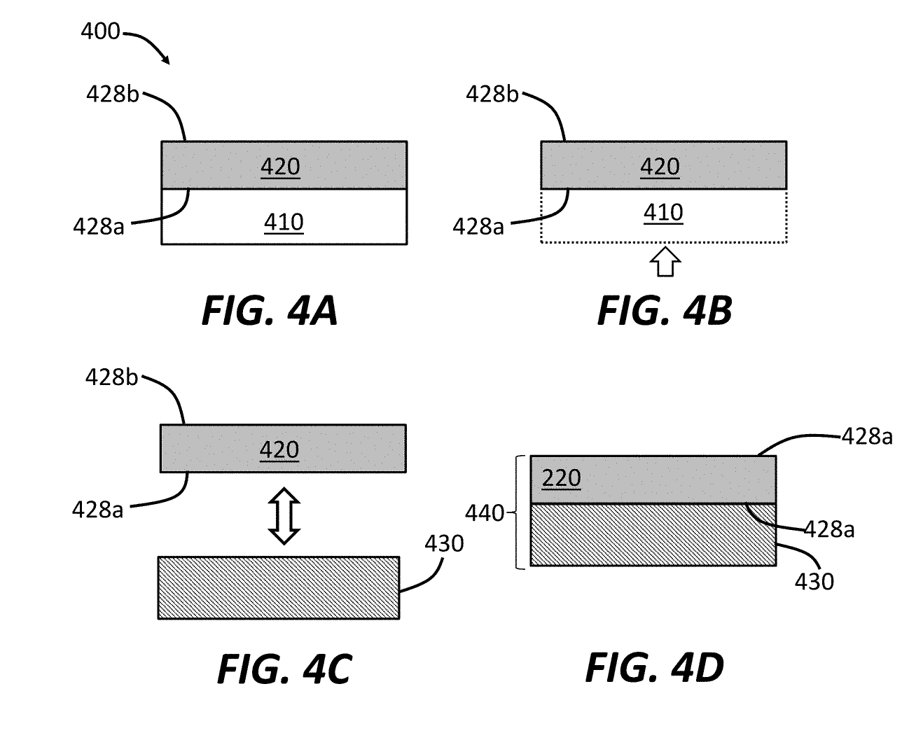

FIGS. 4A-4D illustrate a method 400 of fabricating GaN devices including back etching a growth substrate 410 before wafer bonding. The method 400 includes forming a GaN layer 420 (or GaN stack including at least one GaN layer, see FIGS. 5A-5D below) on the growth substrate 410. The GaN layer 420 has a first surface 428a in contact with the growth substrate 410 and a second surface 428b opposite the first surface 428a.

FIG. 4B shows that the growth substrate 410 is removed, exposing the first surface 428a of the GaN layer 420 for further processing. The removal of the growth substrate 410 can be achieved using any of the methods described above, including mechanical removal, a CMP process, and/or an RIE etching, among others.

FIG. 4C shows that a target substrate 430 (e.g., a SiC substrate or an AlN substrate) is brought in contact with the first surface 428a of the GaN layer 420. The GaN layer 420 and the target substrate 430 are then bonded together to form a stack 440, as shown in FIG. 4D. The stack 440 includes no interlayer between the GaN layer 420 and the target substrate 430, thereby improving the thermal performance of the transistor.

FIGS. 5A-5D illustrate a method 500 of fabricating GaN devices using a handle wafer 530 (also referred to as a handle) to facilitate wafer bonding. The method 500 includes forming a GaN stack 520 on a growth substrate 510 as shown in FIG. 5A. The growth substrate 510 includes a buffer layer 514 disposed on a silicon wafer 512. The buffer layer 514 can include GaN and have a thickness greater than 1 μm (e.g., about 1 μm, about 1.5 μm, about 2 μm, about 2.5 μm, about 3 μm, about 3.5 μm, about 4 μm, about 4.5 μm, about 5 μm, or greater, including any values and sub ranges in between). The GaN stack 520 includes a GaN layer 522 in contact with the buffer layer 514 and an AlGaN layer 524 disposed on the GaN layer 522. A 2DEG layer 523 can be formed between the GaN layer 522 and the AlGaN layer 524. In some cases, the GaN layer 522 and the buffer layer 514 can be epitaxially grown on the silicon wafer 512. The thickness of the buffer layer 514 can be configured such that the GaN layer 522 includes crystalline GaN. In these cases, the buffer layer 514 and the GaN layer 522 can be part of a continuous epitaxial layer grown on the silicon wafer 512.

FIG. 5B shows that the handle wafer 530 is coupled to the GaN stack 520 using an adhesive 535 to bond the handle wafer 530 to the AlGaN layer 524 in the GaN stack 520. The handle wafer 530 can include silicon and can have a thickness substantially equal to or greater than 300 μm (e.g., about 300 μm, about 400 μm, about 500 μm, about 600 μm, about 700 μm, about 800 μm, about 900 μm, about 1 mm or greater, including any values and sub ranges in between). FIG. 5B also shows that the growth substrate 510 is removed to expose the GaN layer 522. Due to the thickness of the growth substrate 510, the removal can be achieved using a combination of mechanical removal and RIE etching. In addition, a CM′ process can also be used to polish the surface after etching.

FIG. 5C shows that the GaN stack 520 is brought to a target substrate 540. In this process, the handle wafer 530 can be used as a handle to physically move the GaN stack 520. In one example, the GaN stack 520 can be manually moved by an operator. In another example, the handle wafer 530 can be coupled to a machine, such as a translation stage, to bring the GaN stack 520 to the target substrate 540. Alternatively, the target substrate 540 can be brought to the GaN stack 520, in which case the handle wafer 530 can be used for holding the GaN stack 520 during bonding.

After the GaN stack 520 is bonded to the target substrate 540, the handle wafer 530 and the adhesive 535 is removed, exposing the AlGaN layer 524 for electrode formation. As shown in FIG. 5D, three electrodes, including a source electrode 550a, a gate electrode 550b, and a drain electrode 550c, are formed on the AlGaN layer 524 so as to form a transistor.

FIG. 5D shows a transistor made from GaN for illustrative purposes. In practice, the GaN layer 522 can be used to fabricate other devices, such as a sensor. In this case, the AlGaN layer 524 can be optional, and the surface of the GaN layer 522 is exposed for further fabrication.

Wafer Bonding Between SiC and GaN

Bonding Chemistry

The methods described above including bonding a GaN layer or a GaN stack with another substrate, such as a SiC substrate. In one example, the SiC substrate can include 6H polytype SiC. In another example, the SiC substrate can include 4H polytype SiC. Both types of SiC have wurtzite crystal structure, but the periodicity and hexagonal symmetry of the lattice structure is different. In addition, the 4H thermal expansion of 4H SiC is more anisotropic than that of 6H SiC.

As understood in the art, a SiC substrate can have two possible faces on its surface: silicon (Si) face or carbon (C) face. A GaN substrate can also have two possible faces on its surface: gallium (Ga) face or nitrogen (N) face. Therefore, SiC and GaN can be bonded in any of four configurations (also referred to as orientations). In a first configuration, the Ga face of a GaN substrate is bonded to the Si face of a SiC substrate (also referred to as the Ga—Si bond). In a second configuration, the Ga face of a GaN substrate is bonded to the C face of a SiC substrate (also referred to as the Ga—C bond). In a third configuration, the N face of a GaN substrate is bonded to the Si face of a SiC substrate (also referred to as the N—Si bond). In a fourth configuration, the N face of a GaN substrate is bonded to the C face of a SiC substrate (also referred to as the N—C bond).

The bonding strength in these configurations can be evaluated by the electronegativity difference of the two interface materials. Electronegativity is a measure of the tendency of an atom to attract a bonding pair of electrons. The Pauling scale is the most commonly used metric to quantify electronegativity. In Pauling scale, Fluorine (the most electronegative element) is assigned a value of 4.0, and values range down to Cesium and Francium which are the least electronegative at 0.7. In general, a larger electronegativity difference between two materials can lead to a stronger bond between these two materials.

TABLE 1
Electronegativity differences for different GaN—SiC bond
configurations.

| | Ga | N |
|---|---|---|
| Si | 0.2 | 1.2 |
| C | 0.9 | 0.5 |

Table 1 shows electronegativity differences for different configurations of GaN—SiC bonding. The electronegativity difference is greatest for Si—N bonds (with a difference of 1.2). The second largest difference occurs between Ga and C, suggesting that Ga—C bond can also be used to achieve a strong bonding. Although Ga—Si bond and N—C bond have relatively smaller electronegativity differences, these bonds can also be used in practice, since bonding strength is just one factor in deciding which configuration to use. Besides electronegativity differences, ab initio calculations of bond distances can also be used to determine GaN—SiC growth interfaces in the four possible configurations.

FIG. 6A illustrates a configuration 601 including Ga—C bonds that bond a GaN substrate with a SiC substrate. In the configuration 601, a GaN substrate 611 is bonded to a SiC substrate 621. The GaN substrate 611 has Ga-polar unit cells on its surface and the SiC substrate has C-polar unit cells on its surface. Therefore, at an interface 631 in the bonded structure, a Ga atom in the GaN substrate 611 is bonded with a C atom in the SiC substrate 621, thereby forming a Ga—C bond.

FIG. 6B illustrates a configuration 602 including Ga—C bonds that bond a GaN substrate with a SiC substrate. In the configuration 602, a GaN substrate 612 is bonded to a SiC substrate 622. The GaN substrate 612 has Ga-polar unit cells on its surface and the SiC substrate has Si-polar unit cells on its surface. Therefore, at an interface 632 in the bonded structure, a Ga atom in the GaN substrate 612 is bonded with a Si atom in the SiC substrate 622, thereby forming a Ga—C bond.

The configurations in FIGS. 6A and 6B use 6H SiC for analysis. The results are also informative in understanding a GaN—SiC(4H) interface. In the Ga—C bond shown in FIG. 6A, the bond distance is about 1.99 Å. In contrast, the bond distance of the Ga—Si bond shown in FIG. 6 is about 2.43 Å. The energy difference between the Ga—C bond and the Ga—Si bond is about −1.07 eV per atom, thereby suggesting a stronger covalent bond in the Ga—C case. Thus, from both a polarity perspective and energy perspective, bonding Ga-faced GaN to C-faced SiC can lead to a greater bonding strength. In addition, this bonding configuration can also cause less disruption of the molecular structure of the terminating materials.

Methods of Bonding GaN with SiC

GaN substrates can be bonded to SiC substrate via at least two types of bonding processes. In one example, GaN can be bonded to SiC via a hydrophilic process (with surface hydroxylation). In this process, the wafers can be wet cleaned via, for example, the RCA process. The cleaned wafers can be rinsed (e.g., using deionized water). The surfaces are then placed in contact, with a mechanical force (e.g., pressure) to press the surfaces against each other to form the bond.

In another example, GaN can be bonded to SiC via a hydrophobic process (without surface hydroxylation). In this process, the wafers can be RCA cleaned, followed by a HF dip. The wafers are then blown dry and the bare surfaces are immediately put into contact. These steps can strip the hydroxide from the surface. During bonding, the H⁺ atoms form H₂ gases and migrate out of the wafer.

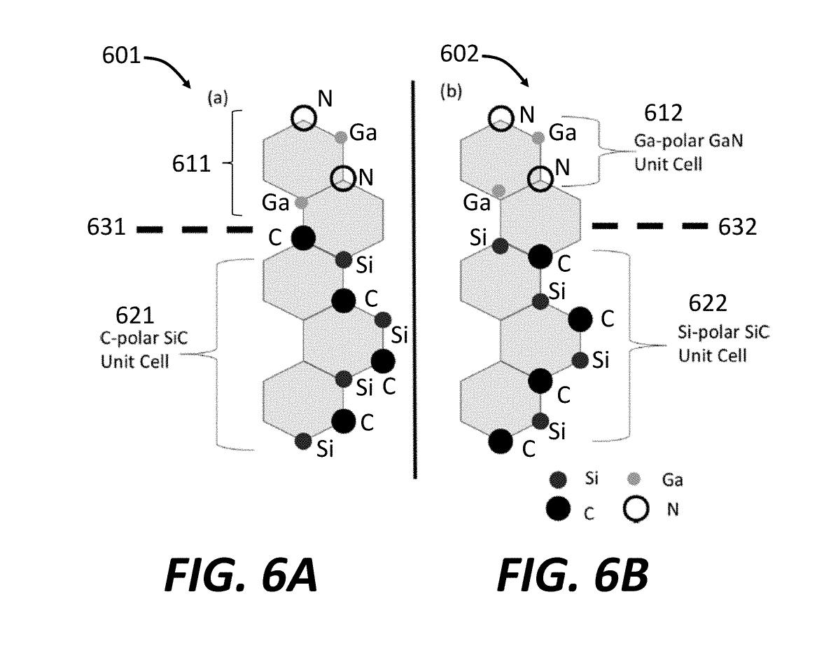

FIG. 7 illustrates a method 700 of bonding GaN with SiC. In general, the method 700 includes, at step 710, cleaning the surfaces of the GaN and SiC substrates via Piranha or RCA process. A plasma treatment is then performed on the cleaned surfaces, at step 720. Preliminary bonding is performed using, for example, a mechanical wafer bonder, to cause initial van der Waals bonding between the GaN and SiC substrates, at step 730. At step 740, these bonded samples are then loaded into a high temperature diffusion furnace for annealing, which can facilitate the formation of covalent bonds between Ga atoms in the GaN substrate and C atoms in the SiC substrate.

In some cases, the preliminary bonding at 730 is optional. For example, the two substrates can be directly bonded at high temperatures (e.g., 1000° C.). In some cases, the preliminary bonding at step 730 and the annealing at step 740 can be consolidated into one step. In this case, a bonder that can withstand high temperatures can be used to bond the two substrates in an annealing furnace.

The surface cleaning at 710 can remove surface contamination and oxidation. The cleaning can also be used to control surface carbon and oxygen levels, and strip any hydroxides on the surface. In one example, the surfaces of the GaN and SiC substrates can be cleaned via the Piranha technique. In this technique, a solution of H₂SO₄:H₂O₂ (e.g., 3:1) can be applied to the substrate surfaces for cleaning. In another example, the surfaces of the GaN and SiC substrates can be cleaned via the RCA technique. For example, an RCA process can include a treatment using H₂O:NH₄OH:H₂O₂ (e.g., 5:1:1) at about 80° C., followed by H₂O:HCl:H₂O₂ (e.g., 6:1:1) at about 80° C. These two techniques (i.e., Piranha and RCA) can remove surface residual carbon and oxygen, so that the surfaces are either activated or —H terminated. Additional HF or HCl dips can be used to remove oxygen from GaN substrates.

The surface activation at step 720 can free surface states and ablate away any contaminants that are not cleaned at step 710. These freed electrons can then form covalent bonds with the other substrate for bonding. In one example, the surface activation can be achieved using ultraviolet-ozone (UV/O₃) surface treatment. In this treatment, organic compounds are converted into volatile substances (e.g., water, carbon dioxide, nitrogen) and removed by decomposition under ultraviolet (UV) radiation and by strong oxidation during the formation and decomposition of O₃. In another example, Ar plasma can be used to activate the substrate surfaces. In yet another example, He plasma can be used for surface activation.

In practice, it can be desirable to perform surface action (e.g., step 720) or any other bonding steps immediately after cleaning. Control over surface chemistry can be lost soon after the samples are removed from the cleaning solutions. For example, standard wafer boxes can sublime hydrocarbons, which can contaminate the bonding surface. Storing cleaned wafers for a prolonged time before bonding can therefore reduce bonding effectiveness.

After surface activation, the wafers can be promptly put into contact and undergo initial bonding at step 730. This process can include the application of mechanical pressure at an elevated temperature (e.g., greater than 100° C., greater than 200° C., or greater than 300° C., including any values and sub ranges in between) under either vacuum or non-reactive atmosphere. The pressure can be applied at the center of the substrates, with flags holding the edges of the two substrates apart. These flags are then removed and the bond are allowed to propagate to the edges, thereby reducing voiding. Voiding can result from a variety of factors, such as surface contaminants, chemical reactions, or gases trapped by the bonding front.

Once wafers are bonded together, the bond quality can be improved by prolonged annealing under a high temperature (e.g., greater than 800° C., greater than 900° C., or greater than 1000° C., including any values and sub ranges in between). This annealing step can increase molecular energy so that the activation energy of covalent bonding can be surmounted, i.e., chemical strengthening. The annealing can also cause degassing at the interface.

High Temperature Bonding Fixtures

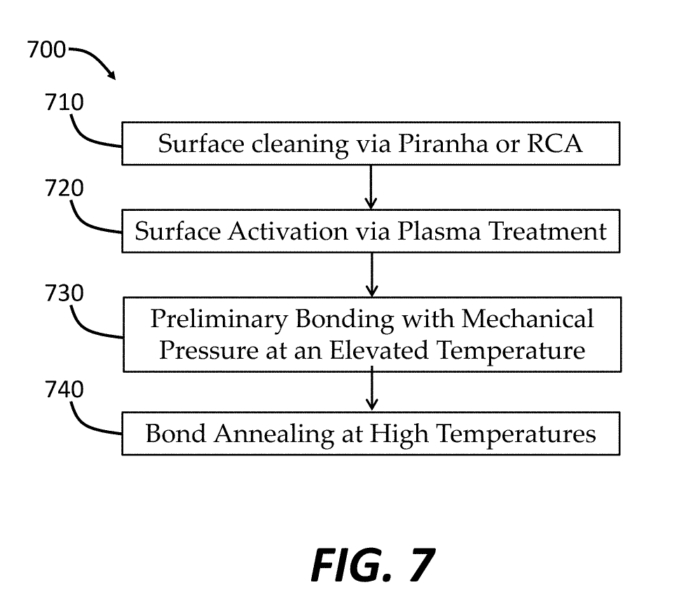

FIGS. 8A and 8B show a cross sectional view and a side view, respectively, of an apparatus 800 for bonding two or more substrates, including bonding GaN substrates with SiC substrates. The apparatus 800 includes a quartz tube 810 functioning as a constraining collar for two graphite half-rods 820. Two graphite shims 830 are attached to the surfaces of the graphite half-rods 820, with each shim attached to a corresponding graphite half-rod. The substrates 840 to be bonded are placed between the two shims 830.

In operation, the apparatus 800 can be in a high temperature environment, and the thermal expansion of the graphite half-rods 820 can provide mechanical pressure to press the substrate 840. The coefficient of thermal expansion for fine-grain graphite is typically at least 2×10⁻⁶ m/mK. In contrast, the coefficient of thermal expansion of the high quality quartz in the quartz tube 810 is typically about 0.77×10⁻⁶ m/mK. Therefore, the pressure applied by the apparatus 800 on the substrates 840 can be about 5.3 MPa (assuming a Young's modulus of 4.1 GPa for graphite). This can be equivalent to over 500 N of force on a 1 cm² substrate. This pressure is also lower than the stress limits for quartz tubing and therefore should not shatter the quartz tube 810.

Characterizations of Wafer Bonded GaN on SiC

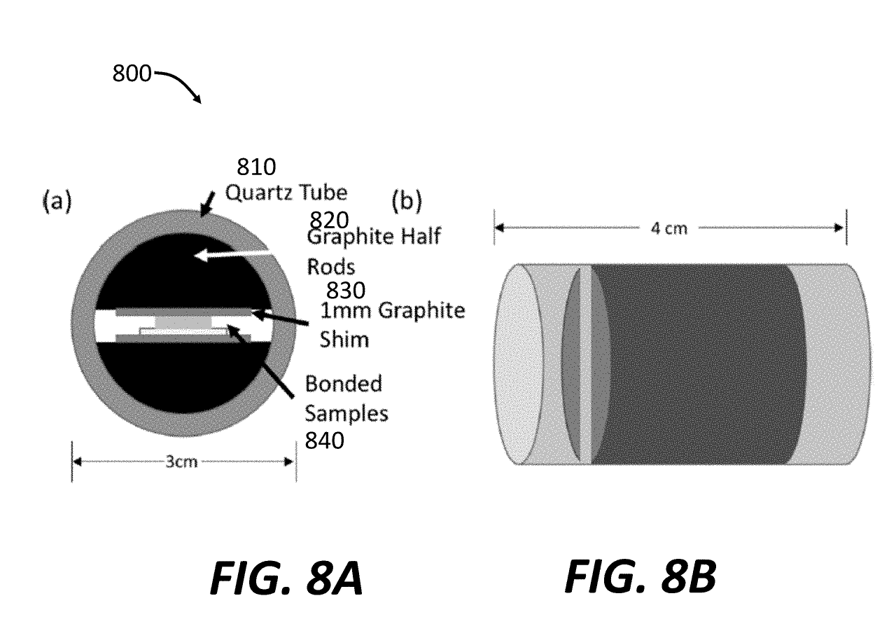

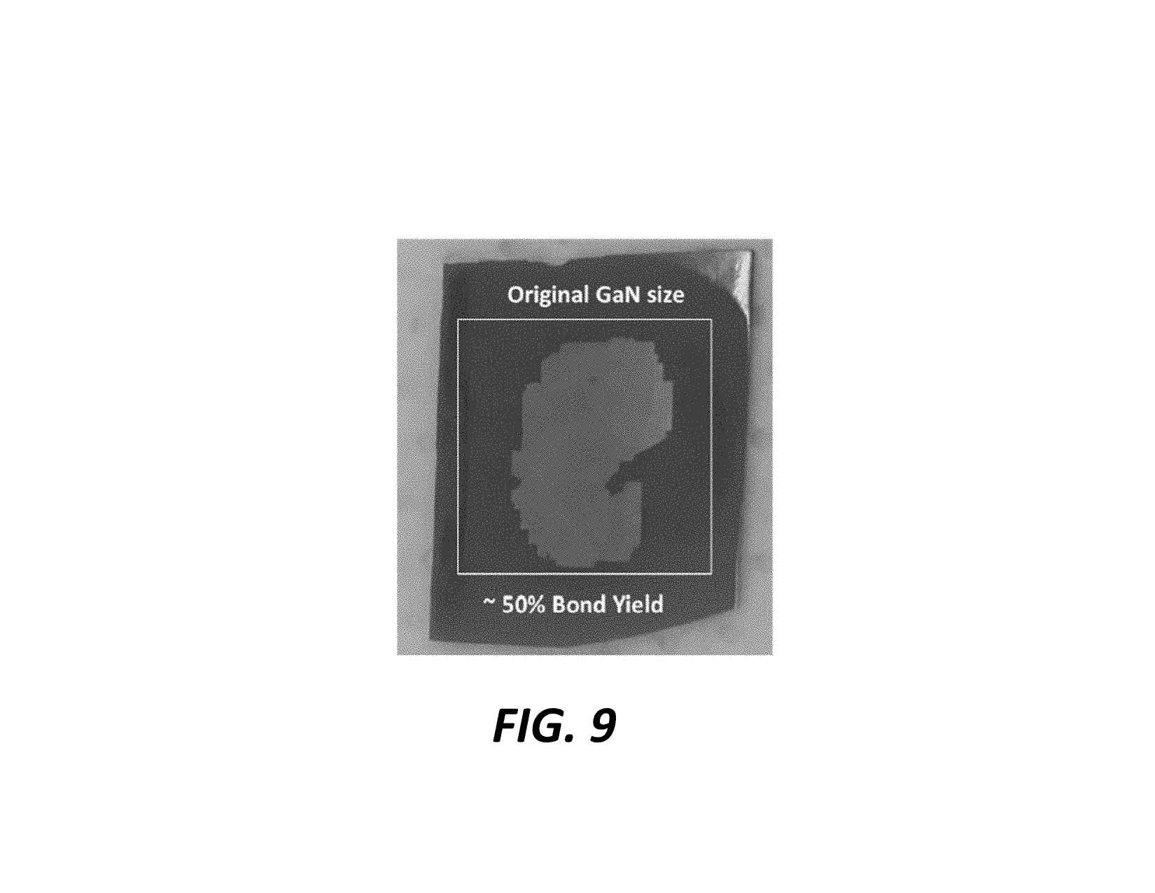

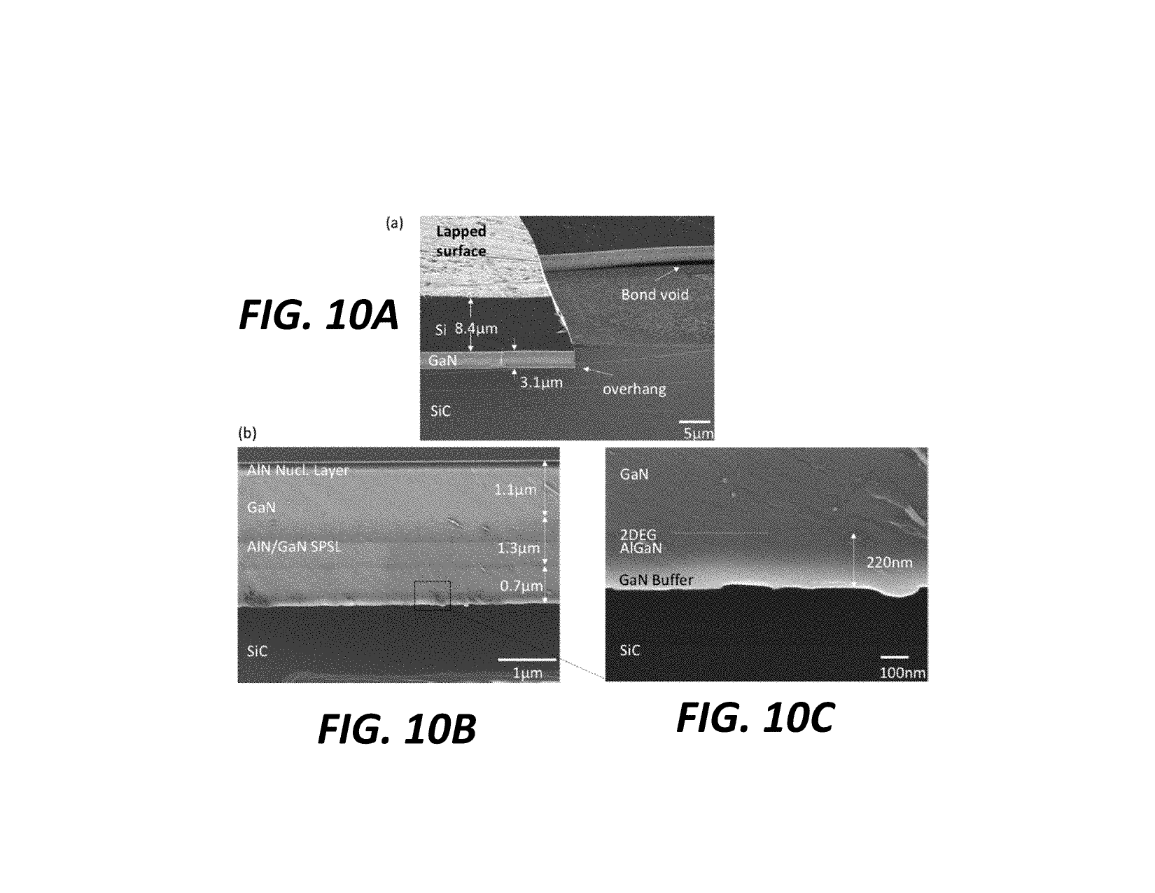

FIG. 9 shows an image of a GaN substrate bonded to a SiC substrate. Over 50% bond yield (in terms of bonded area with respect to the area of the substrate before bonding) is achieved. FIG. 10A shows a He⁺ ion microscopy image of a GaN substrate bonded to a SiC substrate illustrating voids at scribed edge. FIGS. 10B and 10C are side views of the GaN substrate bonded to the SiC substrate shown in FIG. 10A. A sample (e.g., like the one shown in FIG. 9) was scribed and its interface was examined under He⁺ Ion Microscopy, which can have a nominal resolution of about 1 nm and can excite the SiC such that details were more visible. The interface appears to be of good quality, with a thin amorphous region in the GaN buffer. While some microscopic voiding was observed, there was not a visibly significant amount. Overall, the bonding resulted in a good quality stack, with a predominantly cohesive crystalline interface. The samples shown in FIG. 9 and FIGS. 10A-10C were prepared as follows.

The SiC substrate is a 4H SiC wafer from Novasic, Inc. with C-face epi-ready polishing. The wafer was then diced into 1.5 cm×1.5 cm pieces. Thick resist was used to protect the bonding surfaces during this processing. The resist was not baked so as to allow for easy removal. A triple solvent clean was then performed, with a 15 minute sonication in acetone to begin the clean. A double piranha clean removed any contaminants or particulates from the dicing/scribing process.

TABLE 2
Epitaxial growth structure used in wafer bonding experiments.

| Layer | Material | Thickness | |
|---|---|---|---|
| Layer 6 | GaN | 150 | nm |
| Layer 5 | AlGaN 27% | 18 | nm |
| Layer 4 | AlN | 1 | nm |
| Layer 3 | GaN | 30 | nm |
| Layer 2 | AlGaN 27% | 10 | nm |
| Layer 1 | GaN Buffer/SPSL | 2.6 | μm |
| Layer 0 | AlN | 240 | nm |
| Substrate | Si(111) | 1.1 | mm |

The GaN wafer was grown via molecular beam epitaxy. The resulting growth structure is listed in Table 2 and the wafers were 200 mm in diameter. The short-period superlattice (SPSL) had a 49 nm period with roughly 30 periods. Additional GaN buffer material was grown before and after the SPSL. As the SPSL was to be etched away, no Fe³⁺ ion doping was used. The GaN wafer was diced into 1.2 cm×1.2 cm pieces, and the same surface protection and cleaning processes were applied as with the SiC pieces. The surface roughness of both the GaN and the SiC were measured via AFM. A 100 μm² area of a GaN sample had an RMS roughness of about 7.87 Å. A similar measurement on an SiC sample yielded a RMS roughness of about 1.71 Å.

The bonding process includes the following steps. The substrates first underwent a 10 minute Piranha cleaning, followed by 2 minutes in DI water for rinsing at 25° C. Then another 2 minute of DI water rinse was performed at 90° C. A 10 minute dip in 10:1 H₂O:HF was performed to improve cleaning, followed by 2 minutes DI rinse at 25° C. and N2 blow dry. The surface activation was carried out using Ar Plasma. The initial bonding includes 1 hour at about 500° C. in a vacuum environment (e.g., about 10⁻³ mtorr). The mechanical force applied to the substrates was about 1500 N. The annealing step was performed at about 1000° C. for about 1 hour. During annealing, the bonded substrates were placed under N₂ to avoid oxidation.

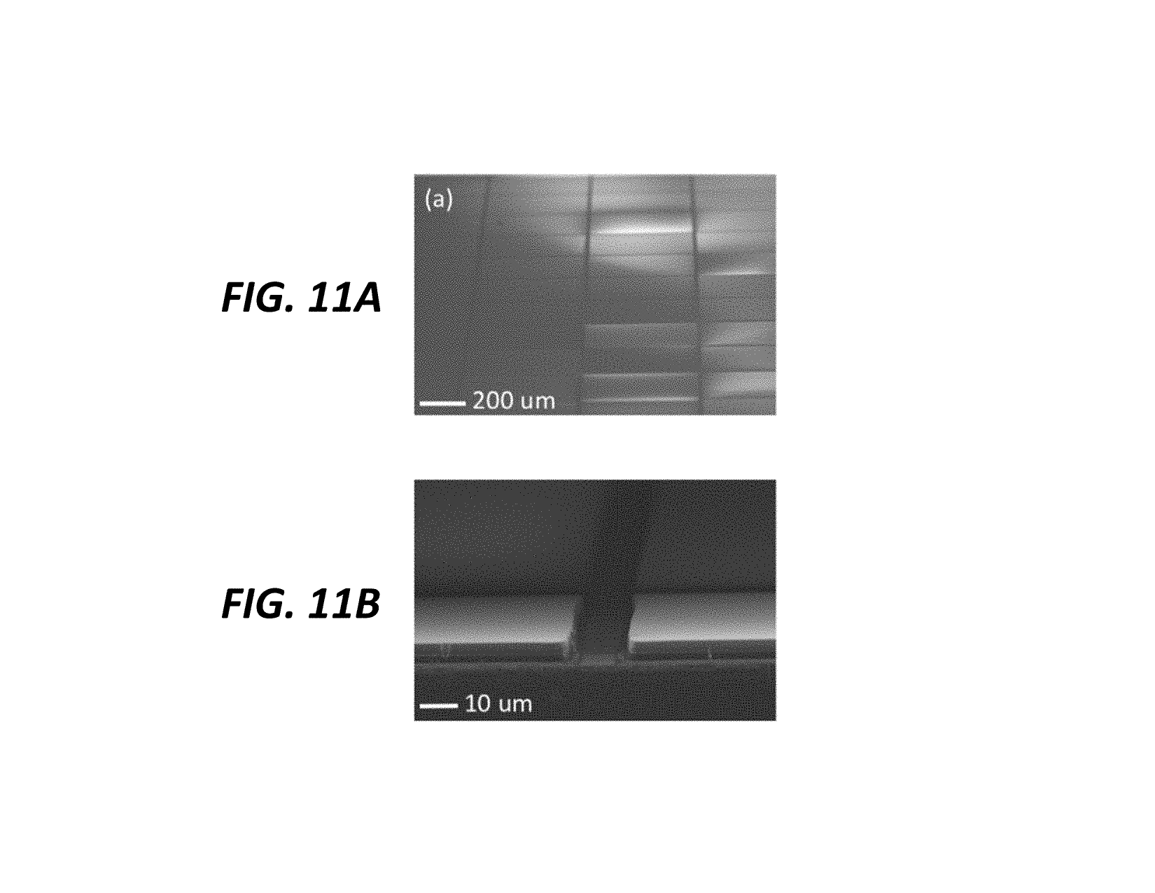

FIGS. 11A and 11B show SEM images of GaN substrates including stress relieving channels. These etched channels can function as a stress relieving mechanism for heterogeneous bonding. By allowing the smaller pads of GaN material to expand and contract more freely, they can reduce the bonding stress. The stress relieving channels can also improve gas flow at the interface (e.g., through the channels), thereby aiding in the dissociation mechanism described above. To fabricate these structures, a mask with 300, 500, and 1000 μm pads was made, with channels to separate neighboring pads. The width of the channels can also be about 1 μm to about 50 μm (e.g., about 1 μm, about 2 μm, about 5 μm, about 10 μm, about 20 μm, or about 50 μm, including any values and sub ranges in between). In FIGS. 11A and 11B, channels that were about 10 μm wide were used. A 2 μm high frequency oxide layer was deposited on the pieces, and standard positive lithography was used to open the channels in the resist. The oxide was then etched via Cl-based plasma. The GaN and underlying layers were etched with Cl₂/BCl₃ high powered plasma (at a rate of about 250 nm/minute).

The GaN was slightly over-etched to ensure complete removal in the channels. After etching, samples underwent an HF dip to remove the oxide; a surface profilometer was used to measure the channel thickness. The surface roughness was measured via AFM and found to be 6.91 Å.

Thermal Performances of GaN Devices Fabricated Via Wafer Bonding

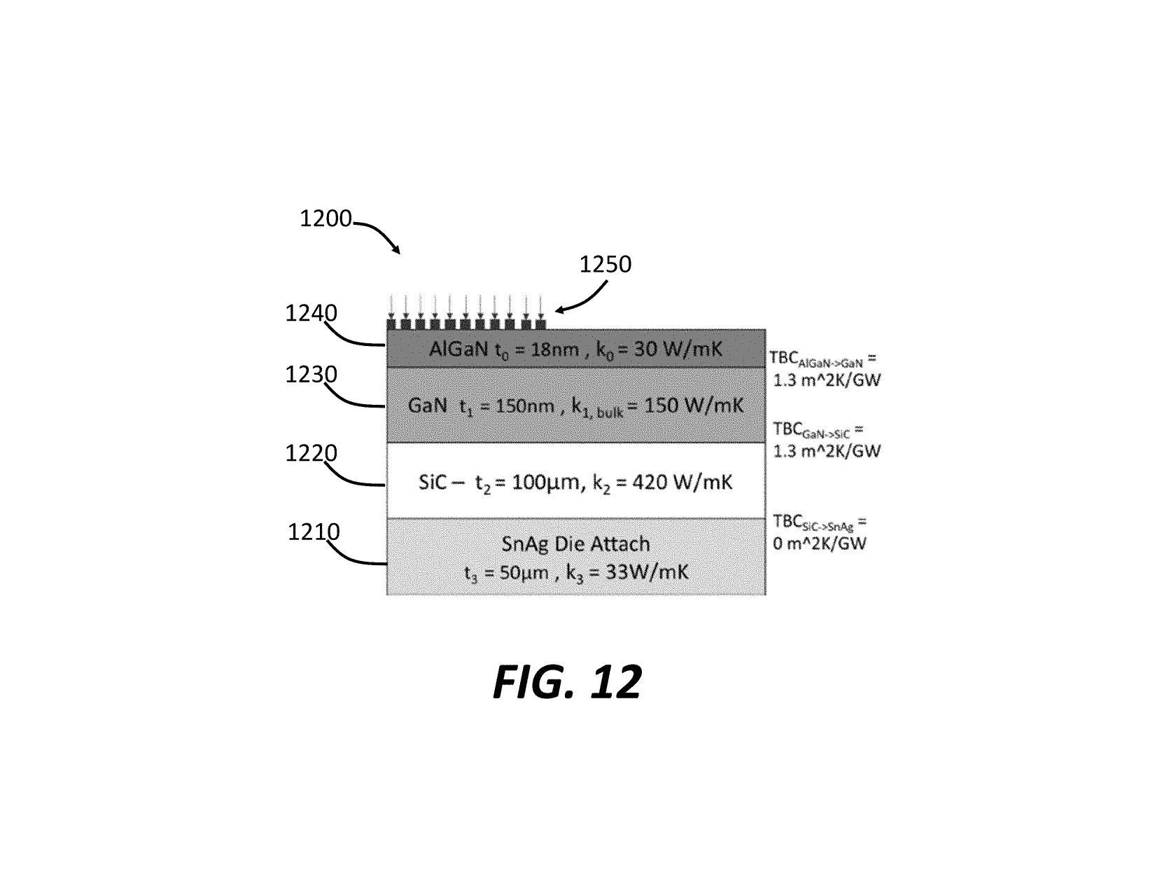

FIG. 12 shows a model 1200 used to simulate thermal performances of GaN transistors. The mode 1200 includes a SnAg die attach layer 1210 and a SiC substrate 1220 disposed on the attach layer 1210. A GaN layer 1230 is bonded to the SiC substrate 1220 and an AlGaN layer 1240 is disposed on the GaN layer 1230. The model also includes an array of electrodes 1250 disposed on the AlGaN layer 1240. This model 1200 can be fabricated via the method 300 illustrated in FIGS. 3A-3D.

The GaN—SiC thermal boundary resistance (TBR) can be derived using a diffuse mismatch model (DMM), which estimates the TBR at about 1.31 m²K/GW. This value presents a strong upper bound on the interfacial conductivity, and the measured TBRs including nucleation layer present a good lower bound at 4-5 m²K/GW. For the TBR of the AlGaN—GaN interface, the DMM calculation estimates that 1 m²K/GW is an upper bound. Finally, for the AlGaN layers a 30 W/mK conductivity was used.

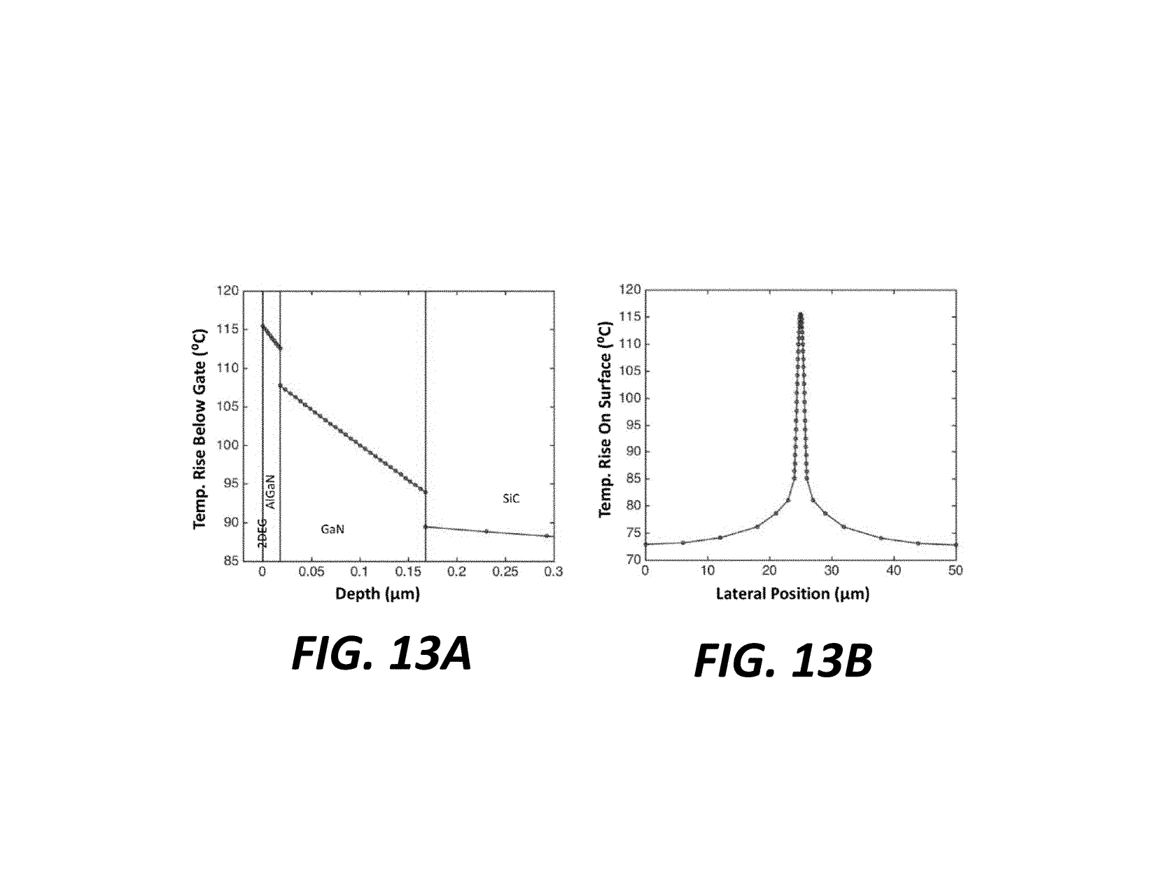

FIGS. 13A and 13B show calculated results of temperature increase below the gate and on the surface, respectively, of the model shown in FIG. 12. The simulation uses 5 W/mm input power to the device. The maximum temperature in this device is about 115.5° C. (FIG. 13B), which is significantly lower than a standard GaN-on-SiC structure, as well as the GaN-on-Diamond average case. Like the standard GaN-on-SiC, the bonded HEMT has a surface temperature minimum of about 72.7 C, with a similar peak sharpness. As is seen in FIGS. 13A and 13B, the reduction of resistance in the GaN buffer can significantly make up for the increased resistance of the AlGaN layer when compared with GaN-on-diamond.

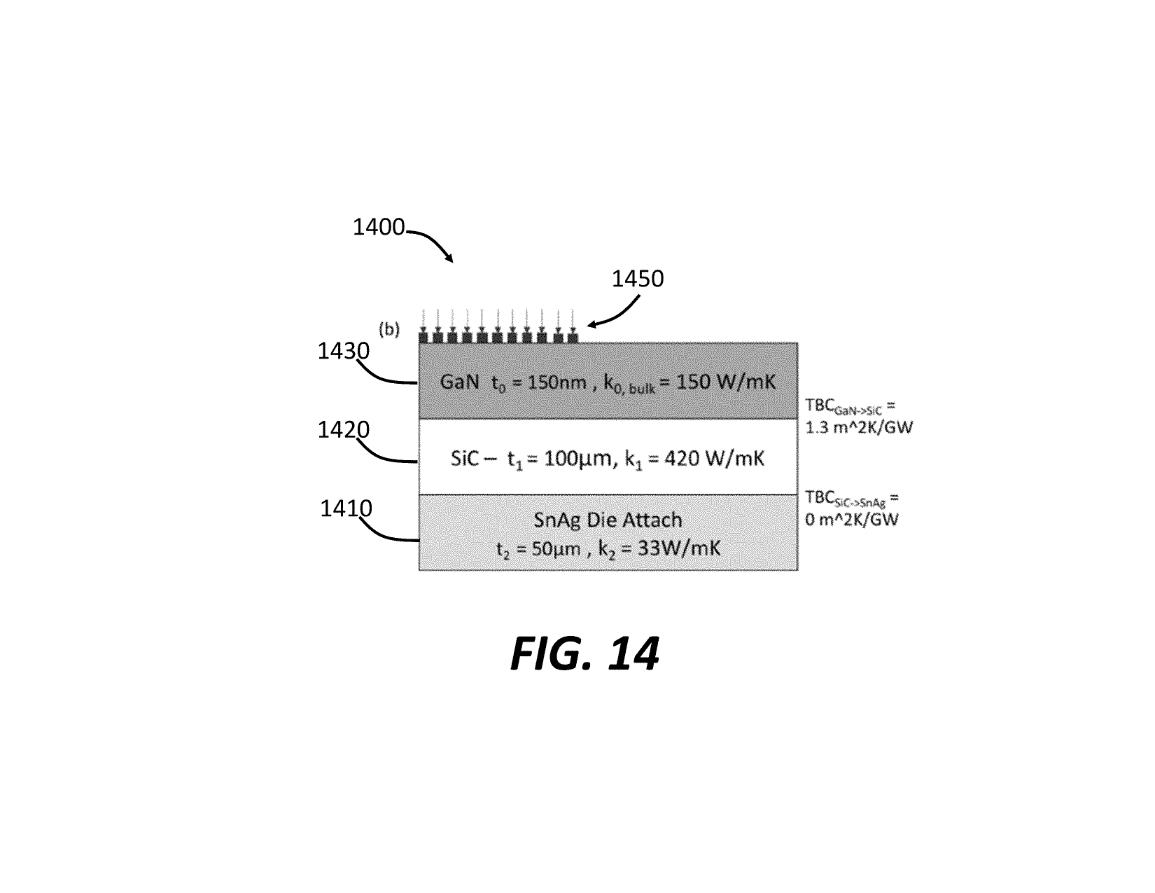

FIG. 14 shows a model 1400 used to simulate thermal performances of GaN transistors without AlGaN layers. The mode 1400 includes a SnAg die attach layer 1410 and a SiC substrate 1420 disposed on the attach layer 1410. A GaN layer 1430 is bonded to the SiC substrate 1420 and an array of electrodes 1450 is disposed on the GaN layer 1430. This model 1400 can be fabricated via the method 500 illustrated in FIGS. 5A-5D.

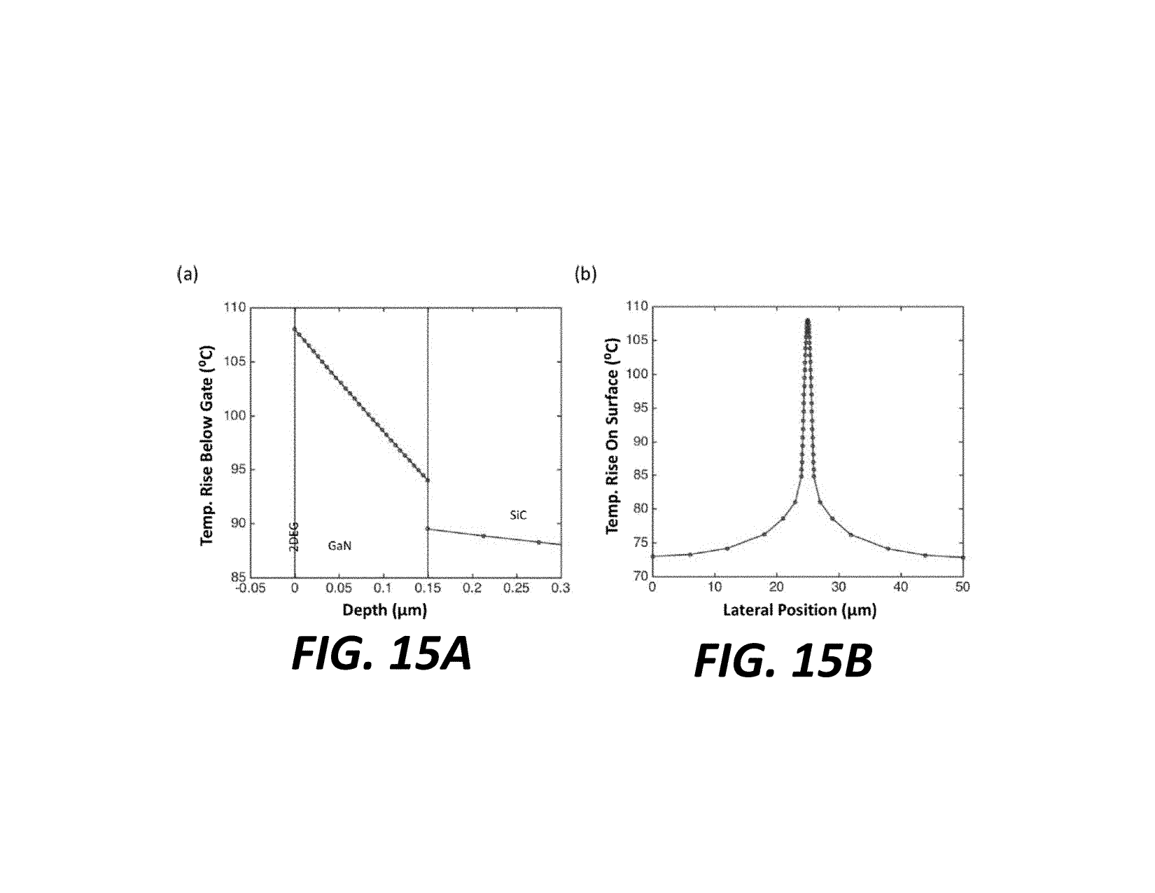

FIGS. 15A and 15B show simulated temperature rise at 5 W/mm power dissipation under central heat source and on surface around central heat source, respectively, using the model 1400 shown in FIG. 14. In the mode 1400, the end structure is simpler, compared to the structure of the model 1200. The max temperature rise was only 107.9° C., with a very low percentage of the thermal resistance found in the near junction.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method comprising:
forming a GaN layer on a first substrate, the GaN layer having a first surface in contact with the first substrate and a second surface opposite the first surface;
bonding the second surface to a second substrate comprising at least one of SiC or AN; and
etching the first substrate to expose the first surface of the GaN layer.

2. The method of claim 1, wherein forming the GaN layer comprises depositing the GaN layer via Metal-Organic Chemical Vapor Deposition (MOCVD) on the first substrate.

3. The method of claim 1, wherein the first substrate comprises silicon.

4. The method of claim 1, wherein the GaN layer has a dislocation density substantially less than or equal to 10¹⁰/cm² on the second surface after bonding.

5. The method of claim 1, wherein bonding the second surface comprises:
exposing at least one of the second surface of the GaN layer or the second substrate to Ar plasma; and
pressing the second surface of the GaN layer against the second substrate at a temperature greater than 800° C. to bond the second surface of the GaN layer to the second substrate.

6. The method of claim 1, wherein the first substrate comprises:
a base substrate;
a buffer layer comprising GaN disposed on the base substrate; and
an etch stop layer comprising AlGaN disposed on the buffer layer.

7. The method of claim 6, wherein etching the first substrate comprises:
etching the buffer layer in the first substrate using a first etching solution; and
etching the etch stop layer in the first substrate using a second etching solution to expose the first GaN film.

8. The method of claim 1, wherein forming the GaN layer comprises:
forming a first GaN film on the first substrate;
forming an AlGaN film on the first GaN film; and
forming a second GaN film on the AlGaN film,
wherein bonding the second surface of the GaN layer comprises bonding the second GaN film to the second substrate, and
wherein etching the first substrate comprises etching the first substrate to expose the first GaN film.

9. The method of claim 8, further comprising:
forming a gate electrode on the first GaN film;
etching the first GaN film to expose a first section of the AlGaN film and a second section of the AlGaN film;
forming a source electrode on the first section of the AlGaN film; and
forming a drain electrode on the second section of the AlGaN film to form a transistor.

10. The method of claim 9, wherein forming the second GaN film comprises forming the second GaN film at a thickness substantially equal to or greater than 50 nm.

11. The method of claim 1, further comprising:
etching the first surface of the GaN layer to remove at least one defect on the first surface.

12. The method of claim 11, wherein etching the first surface of the GaN layer comprises removing about 10 nm to about 50 nm of GaN from the GaN layer.

13. The method of claim 11, wherein etching the first surface of the GaN layer comprises exposing an N-face of GaN.

14. The method of claim 11, wherein etching the first surface of the GaN layer comprises exposing a Ga-face of the GaN.

15. A method comprising:
forming a GaN layer on a first substrate;
etching the first substrate to expose a first surface of the GaN layer; and
bonding the first surface of the GaN layer to a second substrate comprising at least one of SiC or AlN.

16. The method of claim 15, wherein the GaN layer has a dislocation density substantially equal to or less than 10¹⁰/cm² on the first surface after bonding.

17. The method of claim 15, wherein bonding the first surface comprises:
exposing at least one of the first surface of the GaN layer or the second substrate to Ar plasma; and
pressing the first surface of the GaN layer against the second substrate at a temperature greater than 800° C. to bond the first surface of the GaN layer to the second substrate.

18. The method of claim 15, further comprising:
forming a handler layer on a second surface, opposite the first surface, of the GaN layer; and
etching the handler layer to expose the second surface of the GaN layer after bonding the first surface of the GaN layer to the second substrate.

19. The method of claim 15, wherein the first substrate comprises:
a base substrate;
a buffer layer comprising GaN disposed on the base substrate; and
an etch stop layer comprising AlGaN disposed on the buffer layer.

20. The method of claim 19, wherein etching the first substrate comprises:
etching the buffer layer in the first substrate using a first etching solution; and
etching the etch stop layer in the first substrate using a second etching solution to expose the first GaN film.

21. The method of claim 15, wherein forming the GaN layer comprises:
forming a first GaN film on the first substrate;
forming an AlGaN film on the first GaN film; and
forming a second GaN film on the AlGaN film,
wherein etching the first substrate comprises etching the first substrate to expose the first GaN film, and
wherein bonding the first surface of the GaN layer comprises bonding the first GaN film to the second substrate.

22. An apparatus comprising:
a substrate comprising at least one of SiC or AN; and
a GaN layer disposed on the substrate, the GaN layer having a first surface in contact with the substrate and a second surface opposite the first surface, the GaN layer having a dislocation density substantially equal to or less than 10¹⁰/cm² on the first surface.

23. The apparatus of claim 22, wherein the GaN layer has a thickness substantially equal to or greater than 50 nm.

24. The apparatus of claim 22, wherein the GaN layer comprises:
a first GaN film;
an AlGaN film disposed in contact with the first GaN; and
a second GaN film disposed in contact with the AlGaN film and the substrate.

25. The apparatus of claim 24, further comprising:
a gate electrode disposed on the first GaN film;
a source electrode disposed on a first section of the AlGaN film; and
a drain electrode disposed on a second section of the AlGaN film.
